(19) United States
(12) Patent Application Publication
(10) Pub. No.: US 2003/0006809 A1
(43) Pub. Date: Jan. 9, 2003

(54) Capacitor multiplier

(75) Inventor: Leonel Ernesto Enriquez, Melbourne Beach, FL (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: Intersil Americas Inc., Palm Bay, FL

(21) Appl. No.: 09/901,506

(22) Filed: Jul. 9, 2001

(51) Int. Cl. H03K 3/00

(52) U.S. Cl. 327/100

(57) ABSTRACT

A capacitor multiplier/time constant circuit transforms (by approximately a scaling constant k) a relatively small valued capacitor to a much larger valued capacitor in circuit with a relatively small valued resistor. A first of a pair of terminals across which an impedance having a reactance component containing a desired value of capacitance is to be supplied is coupled through a first, relatively small valued resistor to the inverting input of a high input impedance operational amplifier, the output of which is fed back in common with its inverting input terminal. The first terminal is further coupled through a second resistor having a resistance that is a scaling constant multiple of the resistance of the relatively small valued reference resistor, to the non-inverting input of the operational amplifier and to one end of a small reference capacitor, a second end of which is coupled to the second terminal, and an AC (ground) node. The effective capacitance C_{IN} presented to the capacitor multiplier's terminals is on the order of k times the value C of the reference capacitor.

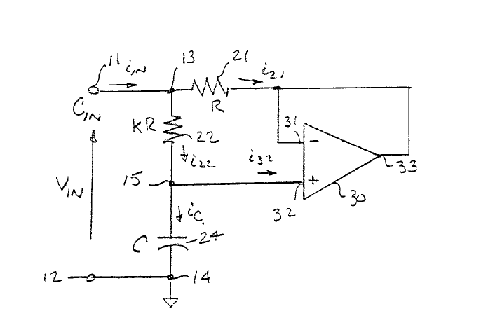

### FIELD OF THE INVENTION

The present invention relates in general to electronic circuits and components therefor, and is particularly directed to a reduced complexity, operational amplifier-based, capacitor multiplier circuit architecture that is especially suited for low voltage, low noise applications, such as, but not limited to subscriber line interface circuits.

### BACKGROUND OF THE INVENTION

Systems employed by telecommunication service providers contain what are known as subscriber line interface circuits or 'SLICS, which interface communication signals with tip and ring leads of a wireline pair serving a relatively remote piece of subscriber communication equipment. In order to be interfaced to a variety of telecommunication circuits, including those with codec functionality, present day SLICs must conform with a very strict set of performance requirements, including accuracy, linearity, insensitivity to common mode signals, low noise, low power consumption, filtering, and ease of impedance matching programmability. They must also comply with a similar set of size and cost restrictions, that constrain the types and values of components that may be used to implement a given circuit design.

### SUMMARY OF THE INVENTION

The present invention is directed to a new and improved capacitor multiplier/time constant circuit that is configured to transform a relatively small valued capacitor (by approximately a scaling constant k) to a much larger valued capacitor in circuit with a relatively small valued resistor, by means of a new and improved, reduced complexity, operational amplifier-based, capacitor multiplier circuit architecture. For this purpose, the capacitor multiplier/time constant circuit of the invention has a pair of terminals across which an impedance having a reactance component containing a desired value of capacitance is to be supplied. One of the terminals is coupled through a first, relatively small valued resistor (e.g., a resistance R on the order of twenty ohms) to the inverting input of a high input impedance operational amplifier, the output of which is fed back in common with its inverting input terminal.

The capacitor multiplier's one terminal is further coupled through a second resistor having a resistance that is a scaling constant multiple of the resistance of the relatively small valued resistor, to the non-inverting input of the operational amplifier and to one end of a reference capacitor, a second end of which is coupled to the second terminal, and an AC (ground) node. The reference capacitor is typically a relatively small valued and therefore small sized component.

Equations which describe the circuit architecture of the capacitor multiplier of the present invention define its impedance Z_{IN} looking into the first and second terminals, to be effectively equal to 1/(sC(k+1))+R/(1+1/k), where s is the Laplace transform parameter. For relatively large values of k (e.g., on the order of 100 or larger), the impedance Z_{IN} becomes 1/(sC(k+1))+R. This implies that the value of the relatively small valued and small sized reference capacitor is synthesized up to a relatively large valued capacitor C_{IN} by a scaling factor (k+1) associated with the ratio of the scaling resistors. Namely, the effective capacitance C_{IN} presented to the capacitor multiplier's terminals is a relatively large or multiplied value (k+1) times the value C of the relatively small reference capacitor, that is coupled in circuit with a similarly small resistor.

### BRIEF DESCRIPTION OF THE DRAWINGS

The single FIGURE is a schematic diagram of an operational amplifier-based capacitor multiplier circuit in accordance with the present invention.

### DETAILED DESCRIPTION

The circuit architecture of the capacitor multiplier of the present invention is schematically illustrated in the single FIGURE as comprising a pair of terminals 11 and 12, the impedance looking into which has a reactance component containing a prescribed value of capacitance C_{IN}. Terminal 11 is coupled to a node 13, while terminal 12 is coupled to an AC reference potential node 14, shown as AC ground. Node 13 is coupled through a first resistor 21, having a resistance value R (e.g., a relatively low value on the order of several tens of ohms, such as 20 ohms), to a first, inverting (−) input 31 of a high input impedance operational amplifier 30, whose output terminal 33 is fed back in common with the amplifier's inverting input terminal 31.

Node 13 is further coupled through a second resistor 22 having a resistance value kR, where k is a multiplying constant associated with the desired value of capacitance C_{IN} to be synthesized across the terminals 11 and 12, as will be described. Resistor 22 is coupled to a node 15, which is connected to a second, non-inverting (+) input 32 of the operational amplifier 30, and to a first terminal of a capacitor 24, a second terminal of which is coupled to the AC ground node 14. Capacitor 24 is typically a relatively small valued and therefore small sized component, having a capacitance value C (to be multiplied or scaled up to the desired synthesized value C_{IN}), and serves as a reference capacitor for the synthesized capacitance C_{IN}.

Equations which describe the circuit architecture of the FIGURE and from which the synthesized capacitance C_{IN} within the reactance component of the circuit's input impedance may be expressed in terms of the reference capacitor C are as follows.

The effective impedance of the reference capacitor 24 may be defined as:

Z₂₄=v_{C}/i_{C}=1/sC (1)

where v_{C} is the voltage across capacitor 24,

i_{C} is the current through capacitor 24, and

s is the Laplace transform parameter.

The current i₂₂ through the resistor 22 which is coupled in series with capacitor 24 across the terminals 11 and 12 may be defined as:

i₂₂=i_{C}+i₃₂ (2)

where i₃₂ is the current into node 32 of operational amplifier 30 and, for a high impedance device, may be presumed to be approximately zero, so that equation (2) may be rewritten as:

i₂₂=i_{C} (3).

The input current i_{IN} applied to node 13 may be defined as:

i_{IN}=i₂₁+i₂₂ (4),

where i₂₁ is the current through resistor 21.

Because of the k ratio of resistors 21 and 22, which are connected in common to node 13, the current i₂₁ through resistor 21 (of resistor value R) is k times larger than the current i₂₂ through resistor 22 (of resistor value kR). Therefore, equation (4) may be rewritten as:

i_{IN}=i₂₂(1+k) (5).

Substituting equation (3) into equation (5) yields:

i_{IN}=i_{C}(1+k) (6).

The voltage v_{IN} across the terminals 11 and 12 may be defined as the sum of the voltage V_{C} across the reference capacitor 28 plus the voltage V₂₂ across series resistor 22 or:

v_{IN}=v_{C}+kRi₂₂ (7).

From equation (3), equation (7) may be rewritten as:

v_{IN}=v_{C}+kRi_{C} (8).

The input impedance Z_{IN} across the terminals 11 and 12 may be defined as:

Z_{IN}=v_{IN}/i_{IN} (9),

which may be rewritten as:

Z_{IN}=(v_{C}+i_{C}kR)/((1+k)i_{C}) (10),

or

Z_{IN}=v_{C}/(i_{C}(1+k))+kR/(1+k) (11),

or

Z_{IN}=1/(sC(k+1))+R/(1+1/k). (12)

For large values of k, equation (12) becomes:

Z_{IN}=1/(sC(k+1))+R. (13)

From equation (13) it can be seen that the effective capacitance C_{IN} within the reactance component of the impedance presented to the terminals 11 and 12 is the value C(k+1). Namely, the value C of the relatively small valued and small sized reference capacitor 24, which is circuit with a relatively small valued resistor (R=on the order of 20 ohms), has been synthesized up to a relatively large valued capacitor C_{IN} by a scaling factor (k+1) associated with the ratio of resistors 22/21.

While I have shown and described an embodiment in accordance with the present invention, it is to be understood that the same is not limited thereto but is susceptible to numerous changes and modifications as known to a person skilled in the art, and I therefore do not wish to be limited to the details shown and described herein, but intend to cover all such changes and modifications as are obvious to one of ordinary skill in the art.

What is claimed:

1. A capacitor multiplier circuit comprising:
first and second terminals across which an impedance containing a prescribed value of capacitance is to be supplied;
a first resistor having a first resistance coupled between said first terminal and an inverting input of an operational amplifier, an output of which is fed back in common with said inverting input;
a second resistor, having a second resistance that is a scaling constant multiple of said first resistance, and being coupled between said first terminal and the non-inverting input of said operational amplifier; and
a reference capacitor coupled between said second resistor and said second terminal.

2. A capacitor multiplier circuit according to claim 1, wherein said prescribed value of capacitance is on the order of k times the value of said reference capacitor, where k is the value of said scaling constant.

3. A capacitor multiplier circuit according to claim 1, wherein said prescribed value of capacitance is (k+1) times the value of said reference capacitor, where k is the value of said scaling constant.

4. A capacitor multiplier circuit according to claim 1, wherein said first resistance is on the order of several tens of ohms.

5. A capacitor multiplier circuit according to claim 1, wherein the impedance Z_{IN} across said first and second terminals, for a relatively large value of said scaling constant is effectively equal to 1/(sC(k+1))+R, where s is the Laplace transform parameter, C is the value of said reference capacitor, k is said scaling constant, and R is the value of said first resistance.

6. A capacitor multiplier circuit comprising a first terminal coupled through a first resistor having a first resistance to an inverting input of an operational amplifier, an output of said operational amplifier being fed back in common with said inverting input thereof, said first terminal being further coupled through a second resistor having a second resistance, that is a scaling constant multiple of said first resistance, to a non-inverting input of said operational amplifier and to one end of a reference capacitor, a second end of said reference capacitor being coupled to a second terminal and to an AC node, such that an impedance of said capacitor multiplier circuit across said first and second terminals includes a reactance component having a prescribed value of capacitance that is on the order of k times the value of said reference capacitor.

7. A capacitor multiplier circuit according to claim 6, wherein said prescribed value of capacitance is (k+1) times the value of said reference capacitor, where k is the value of said scaling constant.

8. A capacitor multiplier circuit according to claim 6, wherein said first resistance is on the order of several tens of ohms.

9. A capacitor multiplier circuit according to claim 6, wherein the impedance Z_{IN} across said first and second terminals, for a relatively large value of said scaling constant is effectively equal to 1/(sC(k+1))+R, where s is the Laplace transform parameter, C is the value of said reference capacitor, k is said scaling constant, and R is the value of said first resistance.

10. A method of synthesizing across first and second terminals a prescribed capacitance from a relatively small valued capacitor comprising the steps of:
(a) coupling a first resistor having a first resistance between said first terminal and an inverting input of an operational amplifier, an output of which is fed back in common with said inverting input;
(b) coupling a second resistor, having a second resistance that is a scaling constant multiple of said first resistance, between said first terminal and the non-inverting input of said operational amplifier; and
(c) coupling said relatively small valued capacitor between said second resistor and said second terminal.

11. A method according to claim 10, wherein said prescribed value of capacitance is on the order of k times the value of said reference capacitor, where k is the value of said scaling constant.

12. A method according to claim 10, wherein said prescribed value of capacitance is (k+1) times the value of said reference capacitor, where k is the value of said scaling constant.

13. A method according to claim 10, wherein said first resistance is on the order of several tens of ohms.

14. A method according to claim 10, wherein the impedance Z_{IN} across said first and second terminals, for a relatively large value of said scaling constant is effectively equal to 1/(sC(k+1))+R, where s is the Laplace transform parameter, C is the value of said reference capacitor, k is said scaling constant, and R is the value of said first resistance.
